(19) United States
(12) Patent Application Publication
(10) Pub. No.: US 2015/0049548 A1
(43) Pub. Date: Feb. 19, 2015

(54) Read Methods for Non-Volatile Memory Devices and Related Non-Volatile Memory Devices

(71) Applicants: Sang-Won Park, Seoul (KR); Dong-Hun Kwak, Hwaseong-si (KR)

(72) Inventors: Sang-Won Park, Seoul (KR); Dong-Hun Kwak, Hwaseong-si (KR)

(21) Appl. No.: 14/459,426

(22) Filed: Aug. 14, 2014

(30) Foreign Application Priority Data
Aug. 16, 2013 (KR) 10-2013-0097281

(51) Int. Cl. G11C 16/26; G11C 16/34

(52) U.S. Cl. CPC G11C 16/26; G11C 16/3427
USPC 365/185.11

(57) ABSTRACT

Read methods for a non-volatile memory device are provided. The read method includes sensing memory cells in an Nth program state using original read voltages of an Nth level, where N is a natural number greater than 2, counting the number of memory cells in the Nth program state according to the sensing result, and when the number of memory cells in the Nth program state is greater than a reference number, sensing memory cells in first to Nth program states using adjusted read voltages of first to Nth levels. The adjusted read voltages are obtained by adding offset voltages to the original read voltages.

### CROSS-REFERENCE TO RELATED APPLICATION

This application claims priority under 35 U.S.C. 119 to Korean Patent Application No. 10-2013-0097281, filed on Aug. 16, 2013 in the Korean Intellectual Property Office, the entire contents of which is hereby incorporated herein by reference.

### FIELD

The present inventive concept generally relates memory devices and, in particular, to a read method for a non-volatile memory device.

### BACKGROUND

Memory devices are largely classified into volatile memory devices and non-volatile memory devices. Volatile memory devices lose data when the power to the device is interrupted. Examples of volatile memory devices may include a static RAM (SRAM), a dynamic RAM (DRAM), a synchronous DRAM (SDRAM) and the like. On the other hand, non-volatile memory devices can store data even when power to the device is interrupted. Examples of the non-volatile memory devices may include a flash memory, a read-only memory (ROM), a programmable ROM (PROM), an electrically programmable read-only memory (EPROM), an electrically erasable programmable read-only memory (EEPROM), a resistive memory, for example, a phase-change RAM (PRAM), a ferroelectric RAM (FRAM), a resistive RAM (RRAM), and the like.

In a charge trap flash (CTF) memory device, a charge redistribution phenomenon may occur due to charge trap of a charge storage layer. The charge redistribution phenomenon may change an amount of charge of the CTF memory cell for a certain period of time after programming. If the CTF memory cell is read using a read voltage of a predetermined level before the certain period of time elapses, a read fail may be generated.

### SUMMARY

Some embodiments of the present inventive concept provide a read method for a non-volatile memory device, the read method includes sensing memory cells in an Nth program state using original read voltages of an Nth level, where N is a natural number greater than 2, counting the number of memory cells in the Nth program state according to the sensing result, and when the number of memory cells in the Nth program state is greater than a reference number, sensing memory cells in first to Nth program states using adjusted read voltages of first to Nth levels. The adjusted read voltages are obtained by adding offset voltages to the original read voltages.

In further embodiments, when the number of memory cells in the Nth program state is not greater than the reference number the method may further include sensing memory cells in first to (N−1)th program states using original read voltages of first to (N−1)th levels.

In still further embodiments, the offset voltages may be varied according to the number of memory cells in the Nth program state.

In some embodiments, the offset voltages may be varied according to the first to Nth program states of the memory cells.

In further embodiments, the offset voltages may increase at higher threshold voltages of the program states or the offset voltages may increase at lower threshold voltages of the program states.

In still further embodiments, the offset voltages may be varied according to the program/erase cycle of the memory cell.

In some embodiments, the offset voltages may correspond to the amount of charge redistribution after programming the memory cells.

In still further embodiments, the adjusted read voltages may be higher than the original read voltages.

In some embodiments, the threshold voltage of the Nth program state among the first to Nth program states of the memory cells may be highest.

Further embodiments of the present inventive concept may provide a read method for a non-volatile memory device, the read method including sensing memory cells in an Nth program state using an original read voltage of an Nth level, where N is a natural number greater than 2; sensing memory cells in a first program state using an original read voltage of a first level while counting the number of memory cells in the Nth program state according to the sensing; and when the number of memory cells in the Nth program state is greater than a reference number, sensing memory cells in second to Nth program states using adjusted read voltages of second to Nth levels. The adjusted read voltages are obtained by adding offset voltages to the original read voltages.

Still further embodiments of the present inventive concept provide a read method for a non-volatile memory device, the method including, when a read operation is performed before a stabilizing time, sensing program states of memory cells using adjusted read voltages; when a read operation is conducted after the stabilizing time, sensing program states of memory cells using original read voltages. The adjusted read voltages are obtained by adding offset voltages to the original read voltages.

### BRIEF DESCRIPTION OF THE DRAWINGS

The above and other features and advantages of the present inventive concept will become more apparent by describing in detail embodiments thereof with reference to the attached drawings in which:

FIG. 1 is a block diagram illustrating a non-volatile memory device according to some embodiments of the present inventive concept.

FIG. 2 is a diagram illustrating original read voltages and adjusted read voltages of the non-volatile memory device shown in FIG. 1.

FIGS. 3 and 4 are diagrams illustrating offset voltages varied according to program states of memory cells in accordance with some embodiments of the inventive concept.

FIG. 5 is a block diagram of a non-volatile memory device according to some embodiments of the present inventive concept.

FIG. 6 is a chart illustrating an exemplary table including records of offset voltages varied according to the count result of a cell counter in accordance with some embodiments of the present inventive concept.

FIG. 7 is a chart illustrating an exemplary table including records of offset voltages varied according to the program/erase cycle of memory cell and the count result of a cell counter in accordance with some embodiments of the present inventive concept.

FIG. 8 is an exemplary table including records of offset voltages varied according to the count result of a cell counter and program states of memory cells.

FIG. 9 is a flowchart illustrating a read method for a non-volatile memory device according to some embodiments of the present inventive concept.

FIG. 10 is a flowchart illustrating a read method for a non-volatile memory device according to some embodiments of the present inventive concept.

FIG. 11 is a conceptual diagram illustrating a memory cell array of the non-volatile memory device illustrated in FIG. 1.

FIG. 12 is a perspective view illustrating a memory block illustrated in FIG. 11.

FIG. 13 is a cross-section illustrating a memory block illustrated in FIG. 11.

FIG. 14 is a cross-section illustrating a non-volatile memory cell (TS) shown in FIG. 13.

FIG. 15 is an equivalent circuit view illustrating a memory block illustrated in FIG. 11.

FIG. 16 is a block diagram illustrating a memory system including non-volatile memory devices according to some embodiments of the present inventive concept.

FIG. 17 is a block diagram specifically illustrating a memory controller illustrated in FIG. 16.

FIG. 18 is a block diagram illustrating an application example of the memory system shown in FIG. 17.

FIG. 19 is a block diagram illustrating a user system including a solid state drive.

FIG. 20 is a block diagram illustrating a user system including a memory card.

FIG. 21 is a block diagram illustrating a computing system including non-volatile memory devices according to some embodiments of the present inventive concept.

FIG. 22 is a block diagram illustrating a system on chip including non-volatile memory devices according to some embodiments of the present inventive concept.

### DETAILED DESCRIPTION OF EMBODIMENTS

Advantages and features of the present inventive concept and methods of accomplishing the same may be understood more readily by reference to the following detailed description of embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

The present inventive concept will be described with reference to perspective views, cross sections, and/or plan views, in which embodiments of the inventive concept are shown. Thus, the profile of an exemplary view may be modified according to manufacturing techniques and/or allowances. That is, the embodiments of the inventive concept are not intended to limit the scope of the present inventive concept but cover all changes and modifications that can be caused due to a change in manufacturing process. Thus, regions shown in the drawings are illustrated in schematic form and the shapes of the regions are presented simply by way of illustration and not as a limitation.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

When a certain embodiment may be implemented differently, a specific process order may be performed differently from the described order. For example, two consecutively described processes may be performed substantially at the same time or performed in an order opposite to the described order.

As such, variations from the shapes of the illustrations as a result, for example, of manufacturing techniques and/or tolerances, are to be expected. Thus, the exemplary embodiments should not be construed as limited to the particular shapes of regions illustrated herein but may be to include deviations in shapes that result, for example, from manufacturing.

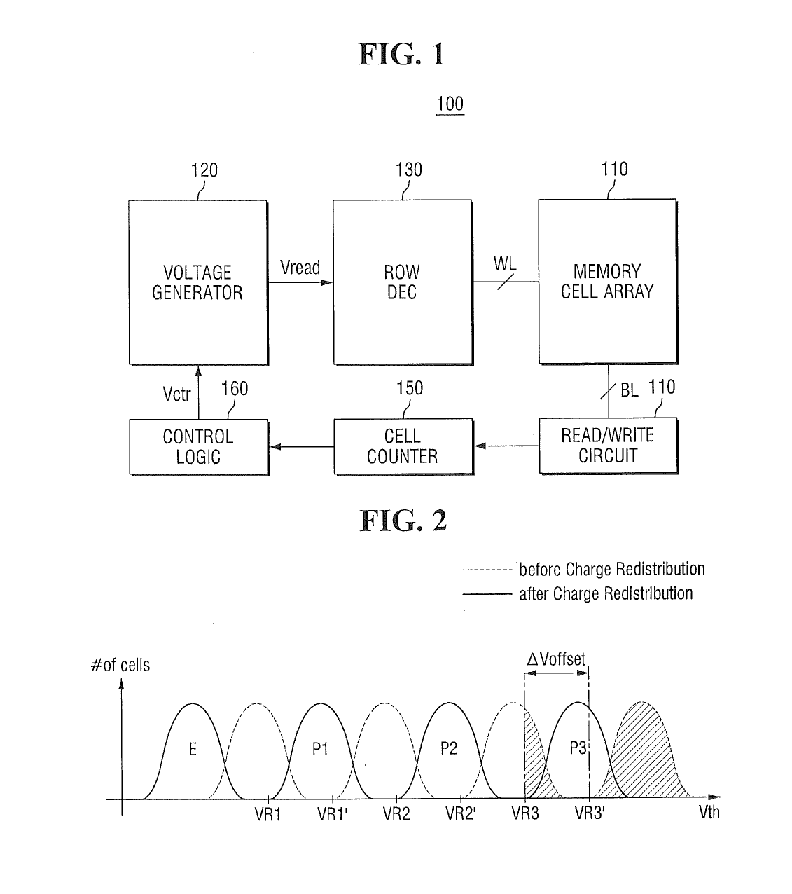

As will be discussed herein, some embodiments of the present inventive concept provide a read method for a non-volatile memory device, which may reduce occurrence of read failures due to charge redistribution. Related non-volatile memory devices are also provided. Hereinafter, non-volatile memory devices according to some embodiments of the present inventive concept will be discussed with respect to FIGS. 1 through 22.

Referring first to FIG. 1 is a block diagram of a non-volatile memory device according to some embodiments of the present inventive concept and FIG. 2 illustrates original read voltages and adjusted read voltages of the non-volatile memory device illustrated in FIG. 1. As illustrated in FIG. 1, the non-volatile memory device 100 according to some embodiments of the present inventive concept includes a memory cell array 110, a voltage generator 120, a row decoder 130, a read/write circuit 140, a cell counter 150, and a control logic 160.

The memory cell array 110 may include a plurality of word lines, a plurality of bit lines and a plurality of memory cells. The respective memory cells may be defined at intersections of the plurality of word lines and the plurality of bit lines. The plurality of memory cells may constitute a plurality of memory blocks, which may constitute a memory cell array.

The memory cell array may be divided into a main region for storing ordinary data and a spare region for storing metadata. The main region and the spare region may be physically or logically divided.

For example, the plurality of memory cells in the main region may be provided as multi level cells (MLCs) each storing two bits. Alternatively, the plurality of memory cells in the main region may be provided as tri level cells (TLCs), but aspects of the present inventive concept are not limited thereto. The plurality of memory cells in the main region may also be provided as memory cells storing two or more bits. For the discussion herein, it will be assumed that the plurality of memory cells in the main region is provided as MLCs. For example, the plurality of memory cells in the spare region may be provided as single level cells (SLCs) each storing one bit.

Each of the memory cells may be a CTF memory cell storing multiple bits. The CTF memory cell traps charges using a charge storage layer, instead of a floating gate.

The voltage generator 120 may generate voltages to be supplied to word lines according to the operating mode of the non-volatile memory device 100. For example, the voltage generator 120 may generate a program voltage Vpgm, a read voltage Vread, and a pass voltage Vpass. Alternatively, the voltage generator 120 may generate voltages to be supplied to bulks having memory cells formed therein. The read voltage Vread may be divided into multiple levels according to program states of memory cells.

The row decoder 130 may be connected to the memory cell array 110 through the word lines WLs. The row decoder 130 may select one of the plurality of memory blocks of the memory cell array 110 and one of the plurality of word lines of the selected memory block. The row decoder 130 may provide voltages generated by the voltage generator 120 to the selected word line and non-selected word lines. In a program mode of the non-volatile memory device 100, for example, the row decoder 130 may provide a program voltage to the selected word line. In a read mode of the non-volatile memory device 100, the row decoder 130 may provide a read voltage to the selected word line. The row decoder 130 may provide a pass voltage to the non-selected word lines.

The read/write circuit 140 may be connected to the memory cell array 110 through a bit line BL. The read/write circuit 140 may write data to the memory cell array 110 or may read data from the memory cell array 110 according to the operating mode of the non-volatile memory device 100. In the program mode of the non-volatile memory device 100, for example, the read/write circuit 140 may function as a write driver, and in the read mode of the non-volatile memory device 100, the read/write circuit 140 may function as a sense amplifier. The read/write circuit 140 may sense program states of the plurality of memory cells disposed on the selected word line using the read voltage.

Referring to FIG. 2, threshold voltage distributions of the non-volatile memory device 100 shown in FIG. 1 are illustrated. The threshold voltage distributions of the respective logic states before charge redistribution are indicated by dotted lines, and the threshold voltage distributions of the respective logic states after charge redistribution are indicated by solid lines.

Each of the memory cells may have one of logic states “E”, “P1”, “P2”, and “P3”. “E” is an erase state, and “P1”, “P2” and “P3” are program states. Each of the memory cells may have a threshold voltage distribution corresponding to each logic state. The first to third program states P1 to P3 may be distinguished from each other by read voltages VR1 to VR3 of first to third levels. The read voltages VR1 to VR3 of first to third levels may be determined in advance based on the threshold voltage distributions of the respective program states P1 to P3 after the lapse of a stabilizing time (i.e., a sufficiently long time for charge redistribution).

Meanwhile, a charge redistribution phenomenon may occur to the CTF memory device due to charge trap of the charge storage layer. Due to the charge redistribution phenomenon, the amount of charges of the CTF memory cell may vary during the stabilizing time after program operations of the respective logic states. With the lapse of the stabilizing time after program operations of the respective logic states, the threshold voltage distributions of the respective logic states may be shifted in such a manner as shown in FIG. 2.

In the third program state P3, for example, there is a difference in the offset voltages ΔV offset between the threshold voltage distribution after charge redistribution and the threshold voltage distribution before charge redistribution. The offset voltages ΔV offset may correspond to the amount of the charge redistribution. Therefore, when the memory cells in the third program state P3 are sensed using the a predetermined read voltage VR3 of the third level before the stabilizing time, a read fail of reading data corresponding to the shaded portion may be generated. Furthermore, when the amount of read failures exceeds a limit value for an error correction block, the read failure is generated.

In the non-volatile memory device 100 according to some embodiments of the present inventive concept, when a read operation is conducted before the stabilizing time, program states of memory cells are sensed using adjusted read voltages VR1′ to VR3′.

However, when a read operation is conducted after the stabilizing time, program states of memory cells are sensed using original read voltages VR1 to VR3. The adjusted read voltages VR1′ to VR3′ may be higher than the original read voltages VR1 to VR3. That is to say, the adjusted read voltages VR1′ to VR3′ may be obtained by adding offset voltages ΔV offset to the original read voltages VR1 to VR3. As discussed above, based on the respective program states P1 to P3, the original read voltages VR1 to VR3 may include threshold voltage distributions of read voltages for predetermined multiple levels after the stabilizing time.

The non-volatile memory device 100 according to some embodiments of the present inventive concept will now be discussed assuming that the read operation is conducted in the order from the first to Nth program states, where N is a natural number greater than 2. The first program state is a logic state in which the non-volatile memory device 100 is programmed for the first time and may refer to a program state, for example, the first program state P1 in FIG. 2, having the lowest threshold voltage among the multiple program states of the memory cells. The Nth program state is a logic state in which the non-volatile memory device 100 is finally programmed and may refer to a program state, for example, the third program state P3 of FIG. 2, having the highest threshold voltage among the multiple program states of the memory cells.

In FIG. 2, the threshold voltage distribution for the case where each memory cell stores 2 bits is illustrated. As discussed above, however, the threshold voltage distribution illustrated in FIG. 2 may also be applied to a case where each memory cell stores 2 or more bits. The threshold voltage distribution illustrated in FIG. 2 may be modified in various manners according to embodiments.

Referring back to FIG. 1, according to the sensing result of the read/write circuit 140, the cell counter 150 may count the number of memory cells in a predetermined program state among the plurality of memory cells of the memory cell array 110. For example, the cell counter 150 may count the number of memory cells in the Nth program state using the original read voltage of the Nth level.

The control logic 160 may control the overall operation of the non-volatile memory device 100. The control logic 160 may receive the number of memory cells in the Nth program state from the cell counter 150 and may transmit a control signal Vctr according to the number of memory cells in the Nth program state. The control logic 160 may determine whether the stabilizing time of the CTF memory cell elapses according to the number of memory cells in the Nth program state.

The voltage generator 120 may generate original read voltages VR1 to VR3 of first to third levels or adjusted read voltages VR1′ to VR3′ of the first to third levels according to the control signal Vctr received from the control logic 160. For example, when the number of memory cells in the Nth program state is in a first range, the voltage generator 120 may generate the original read voltages VR1 to VR3, and when the number of memory cells in the Nth program state is in a second range, the voltage generator 120 may generate the adjusted read voltages VR1′ to VR3′.

The non-volatile memory device 100 may further include a page buffer. The page buffer may store data supplied from an external device, for example, a host or a memory controller, or may store data read from the memory cell array 110.

The memory device 100 illustrated in FIG. 1 determines whether the stabilizing time of the CTF memory cell elapses, and the program states of the memory cells are sensed using the adjusted read voltages VR1′ to VR3′ or the original read voltages VR1 to VR3, thereby reducing occurrence of read failures due to charge redistribution. Although not clearly shown, the offset voltages ΔV offset may be varied based on various parameters to be described below.

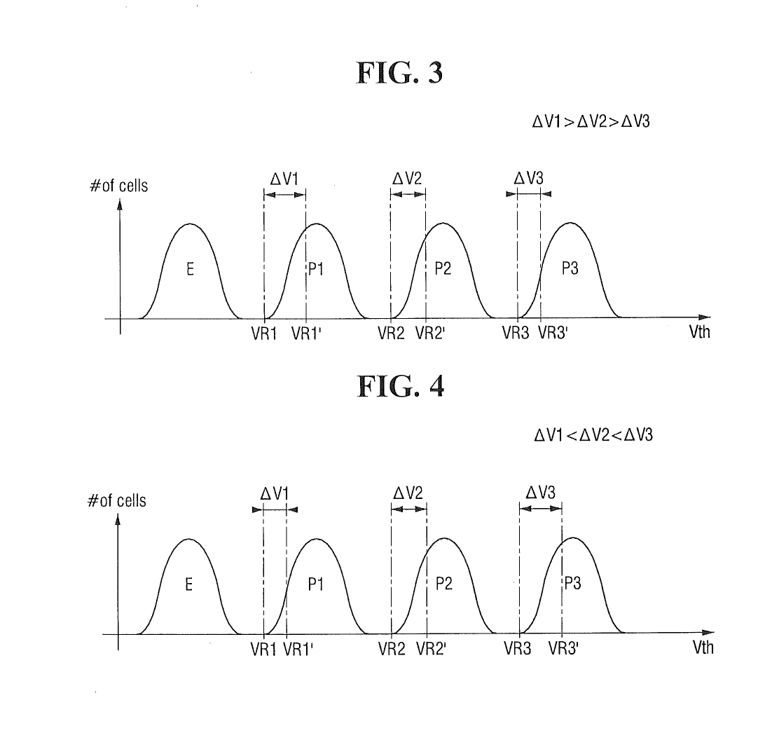

Referring now to FIGS. 3 and 4, diagrams illustrating offset voltages varied according to program states of memory cells will be discussed. As illustrated in FIGS. 3 and 4, the offset voltages ΔV offset may be varied according to the first to Nth program states of the memory cells.

As an example, the offset voltages of one among the plurality of program states of the memory cells, the one having a relatively low threshold voltage, may increase, compared to the offset voltages of a program state having a relatively high threshold voltage. As shown in FIG. 3, the offset voltages ΔV1 for the first program state P1 may be greater than the offset voltage ΔV2 for the second program state P2, and the offset voltage ΔV2 for the second program state P2 may be greater than the offset voltage ΔV3 for the third program state P3. This may be applied to a case where an increased amount of charge redistribution occurs at a lower threshold voltage.

As another example, the offset voltages of one among the plurality of program states of the memory cells, the one having a relatively high threshold voltage, may increase, compared to the offset voltages of a program state having a relatively low threshold voltage. As illustrated in FIG. 4, the offset voltage ΔV3 for the third program state P3 may be greater than the offset voltage ΔV2 for the second program state P2, and the offset voltage ΔV2 for the second program state P2 may be greater than the offset voltage ΔV1 for the first program state P1. This may be applied to a case where an increased amount of charge redistribution occurs at a higher threshold voltage.

Unlike in FIGS. 3 and 4, the offset voltages ΔV1 to ΔV3 for the respective program states P1 to P3 may increase or decrease independently of each other.

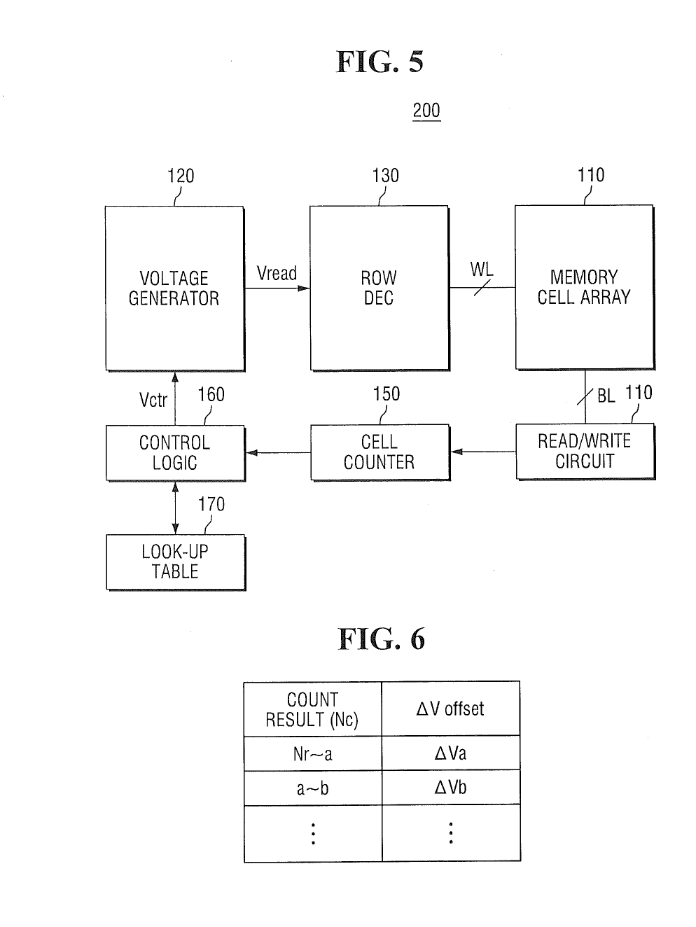

Referring now to FIG. 5, a non-volatile memory device according to some embodiments of the present inventive concept will be discussed. In the interest of brevity, the following description will focus on differences between the non-volatile memory devices illustrated in FIGS. 1 and 5.

Referring to FIG. 5, the non-volatile memory device 200 according to some embodiments of the present inventive concept may further include a look-up table 170, compared to the non-volatile memory device 100 shown in FIG. 1.

The offset voltages ΔVoffset may be recorded in the look-up table 170 based on various parameters. The look-up table 170 may be stored in a non-volatile memory device, such as a read only memory (ROM), to then be provided when necessary. The control logic 160 may generate a control signal Vctr by referring to the offset voltages ΔVoffset stored in the look-up table 170.

Referring now to FIG. 6, an exemplary table including records of offset voltages varied according to the count result of a cell counter will be discussed. As illustrated in FIG. 6, the offset voltages ΔVoffset varied according to the count result of a cell counter 150 may be recorded in the look-up table 170. In the table shown in FIG. 6, “Nc” indicates the number of memory cells in the Nth program state using an original read voltage of an Nth level, and “Nr” indicates a reference number for determining whether the stabilizing time of the CTF memory cell elapses.

For example, when the count result of the cell counter 150 belongs to a range lower than a, the adjusted read voltages VR1′ to VR3′ may be obtained by adding the offset voltage ΔVa to the original read voltages VR1 to VR3. When the count result of the cell counter 150 belongs to a range higher than a and lower than b, the adjusted read voltages VR1′ to VR3′ may be obtained by adding the offset voltage ΔVb to the original read voltages VR1 to VR3. Furthermore, even when the count result of the cell counter 150 is cell counter 150 belongs to a range that is not defined herein, the adjusted read voltages VR1′ to VR3′ may be obtained in substantially the same manner as described above.

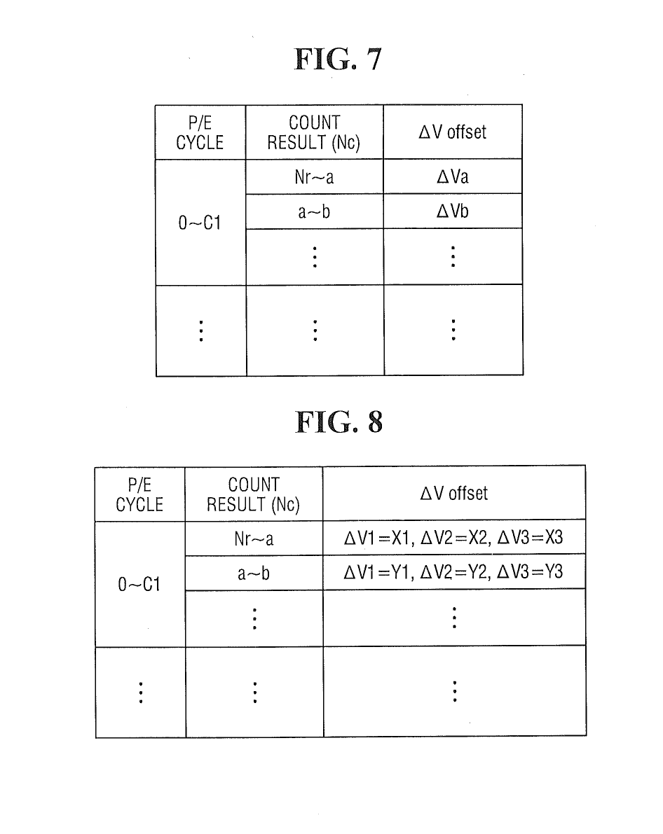

Referring now to FIG. 7, an exemplary table including records of offset voltages varied according to the program/erase cycle of memory cell and the count result of a cell counter will be discussed. As illustrated in FIG. 7, the offset voltages ΔVoffset varied according to the program/erase cycles of memory cells and the count result of the cell counter 150 may be recorded in the look-up table 170. In the table shown in FIG. 7, “P/E CYCLE” indicates the program/erase cycle of memory cell. The look-up table 170 may include the program/erase cycle of memory cell as an upper index and the count result of the cell counter 150 as a lower index.

For example, when the program/erase cycle of memory cell belongs to a range lower than C1 and the count result of the cell counter 150 belongs to a range lower than a, the adjusted read voltages VR1′ to VR3′ may be obtained by adding the offset voltage ΔVa to the original read voltages VR1 to VR3. When the program/erase cycle of memory cell belongs to the range lower than C1 and the count result of the cell counter 150 belongs to a range higher than a and lower than b, the adjusted read voltages VR1′ to VR3′ may be obtained by adding the offset voltage ΔVb to the original read voltages VR1 to VR3. Furthermore, even when the program/erase cycle of memory cell belongs to a range that is not defined herein, the adjusted read voltages VR1′ to VR3′ may be obtained in substantially the same manner as described above.

Referring now to FIG. 8, an exemplary table including records of offset voltages varied according to the count result of a cell counter and program states of memory cells will be discussed. As illustrated in FIG. 8, offset voltages ΔVoffset varied according to program/erase cycles of memory cells, count results of the cell counter and program states of the memory cells may be recorded in the look-up table 170. In the table shown in FIG. 8, “ΔV1”, “ΔV2” and “ΔV3” indicate the offset voltages ΔVoffset for the first to third program states P1 to P3.

For example, when the program/erase cycle of memory cell belongs to a range lower than C1 and the count result of the cell counter 150 belongs to a range lower than a, the adjusted read voltages VR1′ to VR3′ of first to third levels may be obtained by adding offset voltages X1 to X3 to the original read voltages VR1 to VR3 of first to third levels, respectively. When the program/erase cycle of memory cell belongs to the range lower than C1 and the count result of the cell counter 150 belongs to a range higher than a and lower than b, the adjusted read voltages VR1′ to VR3′ of first to third levels may be obtained by adding offset voltages Y1 to Y3 to the original read voltages VR1 to VR3 of first to third levels. Furthermore, even when the program/erase cycle of memory cell belongs to a range that is not defined herein, the adjusted read voltages VR1′ to VR3′ may be obtained in substantially the same manner as described above.

Hereinafter, read methods for the non-volatile memory devices 100 and 200 described with reference to FIGS. 1 to 8 will be discussed. In the interest of brevity, details discussed above will not be repeated herein.

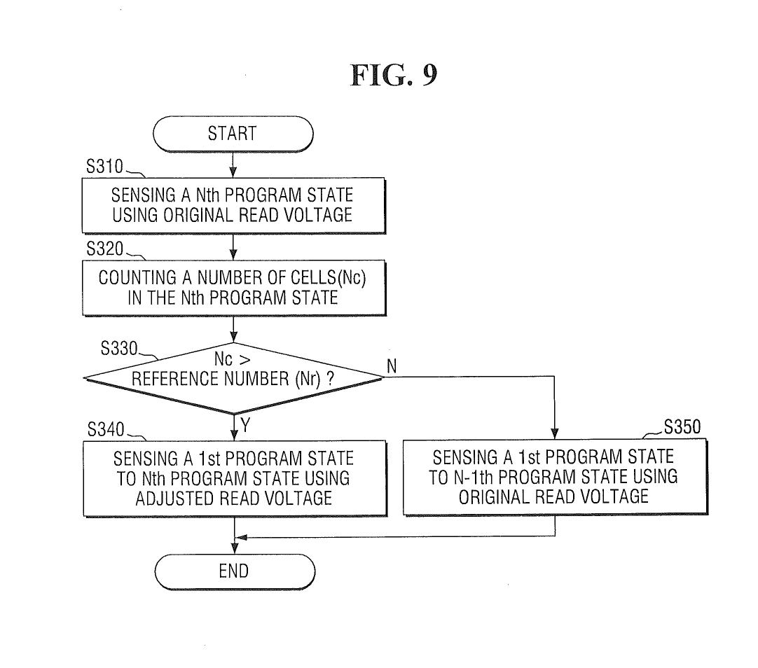

Referring now to FIG. 9, a flowchart illustrating a read method for a non-volatile memory device according to some embodiments of the present inventive concept will be discussed. As illustrated in FIG. 9, in the read method for a non-volatile memory device according to some embodiments of the present inventive concept, first, a read/write circuit 140 senses memory cells in the Nth program state (block S310). The read/write circuit 140 may sense the memory cells in the Nth program state using an original read voltage of an Nth level.

According to the sensing result of the read/write circuit 140, the cell counter 150 counts the number (Nc) of memory cells in the Nth program state (block S320). The control logic 160 determines whether the number Nc of memory cells in the Nth program state is greater than a reference number (Nr) of memory cells (block S330).

When the number Nc of memory cells in the Nth program state is greater than the reference number Nr, the memory cells in first to Nth program states are sensed using adjusted read voltages of first to Nth levels (block S340). At this time, the CTF memory cell has not yet been stabilized. Thus, the control logic 160 may generate control signal Vctr to generate adjusted read voltages, and the voltage generator 120 may generate the adjusted read voltages by adding offset voltages to original read voltages. The read/write circuit 140 senses program states of the memory cells using the adjusted read voltages.

Meanwhile, when the number Nc of memory cells in the Nth program state is not greater than the reference number Nr, the memory cells in first to (N−1)th program states are sensed using the original read voltages of first to (N−1)th levels (block S350). At this time, the CTF memory cell has been stabilized. Thus, program states of the memory cells are sensed using the original read voltages.

In the read method for a non-volatile memory device illustrated in FIG. 9, the sensing result of the memory cells in the Nth program state after stabilizing the CTF memory cell is the same as the sensing result of step S310, the sensing may not further be performed.

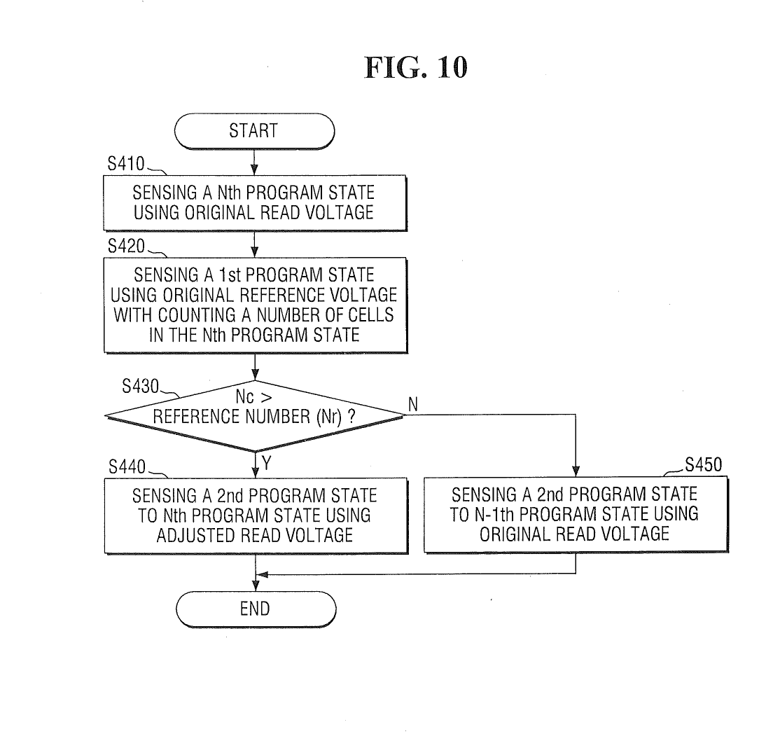

Referring now to FIG. 10, a flowchart illustrating a read method for a non-volatile memory device according to some embodiments of the present inventive concept will be discussed. In the interest of brevity, the following description will focus on differences between the read methods for non-volatile memory devices shown in FIGS. 9 and 10.

Referring to FIG. 10, in the read method for a non-volatile memory device according to some embodiments of the present inventive concept, while the cell counter 150 counts the number Nc of memory cells in the Nth program state according to the sensing result of the read/write circuit 140, memory cells in a first program state are sensed using an original read voltage of a first level (block S420).

When the number Nc of memory cells in the Nth program state is greater than the reference number Nr, the memory cells in second to Nth program states are sensed using adjusted read voltages of second to Nth levels (block S440).

When the number Nc of memory cells in the Nth program state is not greater than the reference number Nr, the memory cells in second to (N−1)th program states are sensed using original read voltages of second to (N−1)th levels (block S450).

In the read method for a non-volatile memory device shown in FIG. 10, the sensing result of the memory cells in the Nth program state after stabilizing the CTF memory cell is the same as the sensing result of block S410, the sensing may not further be performed.

In the read method for a non-volatile memory device shown in FIG. 10, the count operation of the cell counter 150 is conducted at the same time with the sensing of memory cells in the first program state, thereby reducing a loss in the counting performance of the cell counter 150, which may be applied to a case where charge redistribution for the first program state occurs in a negligibly small amount.

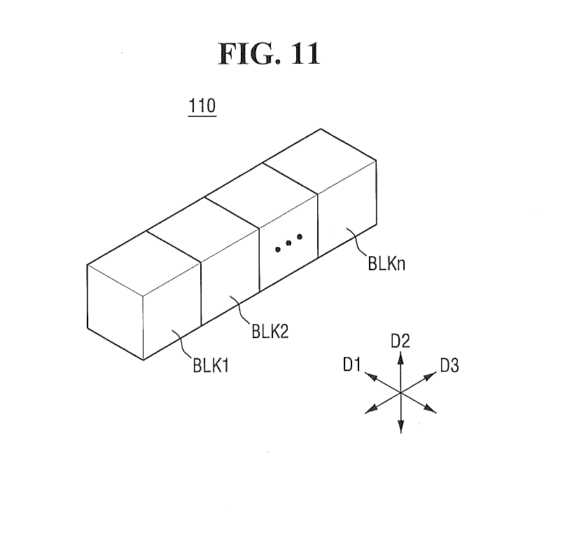

Referring now to FIG. 11, a conceptual diagram specifically illustrating a memory cell array of the non-volatile memory device shown in FIG. 1 will be discussed. As illustrated in FIG. 11, the memory cell array 110 of the non-volatile memory device 100 may include a plurality of memory blocks BLK0 to BLKi, where i is a natural number. The respective memory blocks BLK0 to BLKi may extend in first to third directions D1, D2 and D3.

As illustrated in FIG. 11, the first to third directions D1, D2 and D3 may be directions crossing one another or may be different directions. For example, the first to third directions D1, D2 and D3 may be directions crossing one another at right angle, however, it will be understood that embodiments of the present inventive concept are not limited to this configuration.

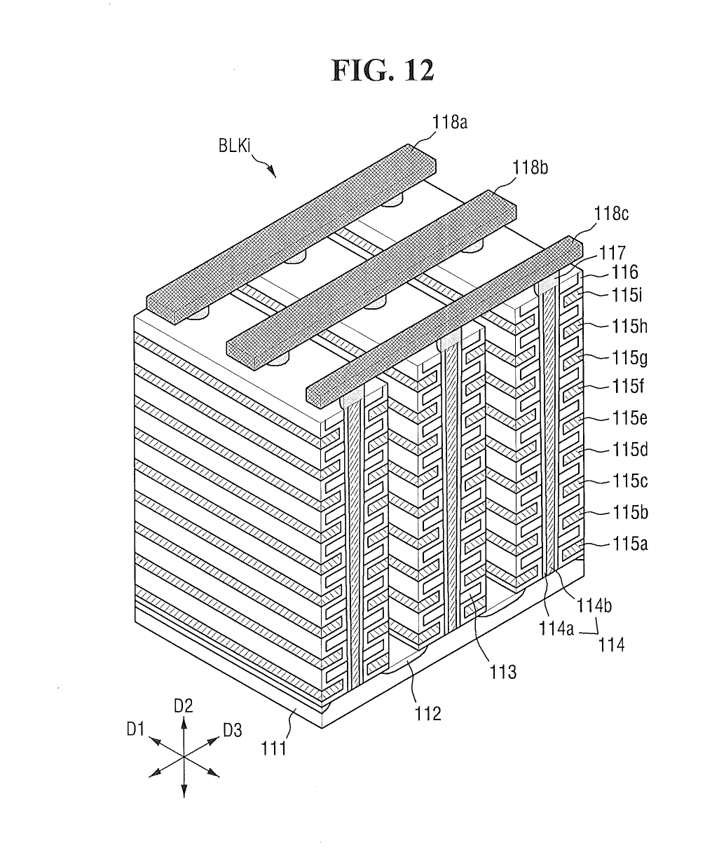

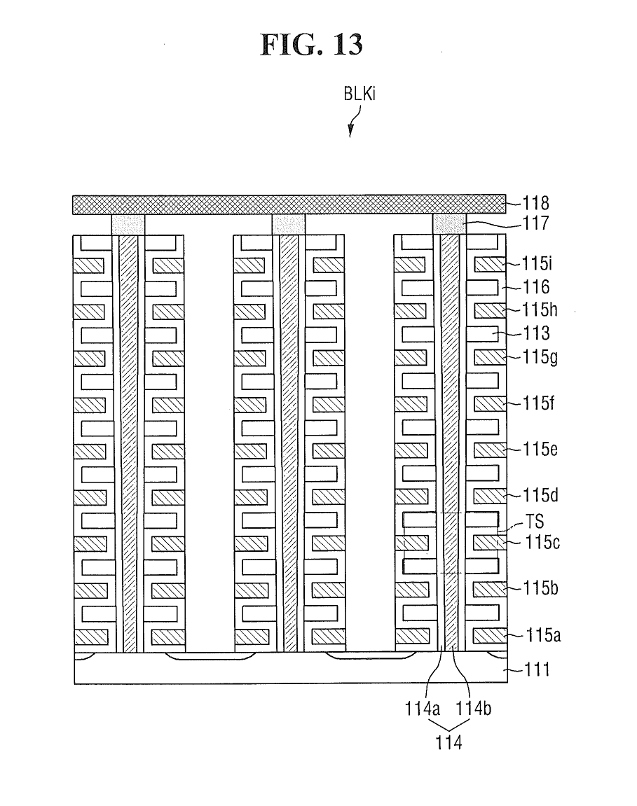

FIG. 12 is a perspective view specifically illustrating a memory block shown in FIG. 11 and FIG. 13 is a cross-section specifically illustrating a memory block shown in FIG. 11. As illustrated in FIGS. 12 and 13, a memory block BLKi includes a substrate 111, a plurality of doping regions 122, a plurality of interlayer insulation layers 113, a plurality of channel structures 114, a plurality of gate patterns 115a to 115i, a plurality of insulation layers 116, a plurality of drain regions 117, and a plurality of bit lines 118a to 118c.

The plurality of doping regions 122 may be provided on the substrate 111. The plurality of doping regions 122 may extend lengthwise in the first direction D1. The substrate 111 may include a silicon material doped with impurity of a first type, and the plurality of doping regions 122 may include a silicon material doped with impurity of a second type. For example, the first type may be p-type and the second type may be an n-type, however, embodiments of the present inventive concept are not limited to this configuration.

The plurality of interlayer insulation layers 113 may be sequentially stacked on the substrate 111 to be spaced apart in the second direction D2. The plurality of interlayer insulation layers 113 may extend lengthwise in the first direction D1. For example, the plurality of interlayer insulation layers 113 may include an insulating material, such as silicon oxide, however, embodiments of the present inventive concept are not limited to this configuration.

The plurality of channel structures 114 may extend lengthwise in the second direction D2 on the substrate 111. In particular, the plurality of channel structures 114 are arranged on the substrate 111 in forms of pillars to pass through the stacked plurality of interlayer insulation layers 113.

The plurality of channel structures 114 may be arranged to be spaced apart from each other in the first and third directions D1 and D3. In other words, the plurality of channel structures 114 may be arranged in a matrix configuration. In FIG. 12, the plurality of channel structures 114 are arranged in a 3×3 matrix configuration, however, embodiments of the present inventive concept are not limited to this configuration.

Each of the plurality of channel structures 114 may include a surface layer 114a and an internal layer 114b. For example, the surface layer 114a may include a silicon material doped with impurity of the same type with that of the substrate 111, however, embodiments of the present inventive concept are not limited to this configuration. For example, the internal layer 114b may include an insulating material, such as silicon oxide, however, embodiments of the present inventive concept are not limited to this configuration.

The plurality of gate patterns 115a to 115i may be sequentially stacked between the plurality of interlayer insulation layers 113 to be spaced apart in the second direction D2. The plurality of gate patterns 115a to 115i may extend lengthwise in the first direction D1. The plurality of gate patterns 115a to 115i may be arrange to be spaced apart from the plurality of channel structures 114. In the illustrated embodiment, the plurality of gate patterns 115a to 115i having the same thickness are exemplified. However, the plurality of gate patterns 115a to 115i may have different thicknesses. For example, the plurality of gate patterns 115a to 115i may include a conductive material, such as tungsten (W), cobalt (Co) or nickel (Ni), or a silicon material, such as silicon, however, embodiments of the present inventive concept are not limited to this configuration.

The plurality of insulation layers 116 may be arranged between the plurality of channel structures 114 and the plurality of gate patterns 115a to 115i. The plurality of insulation layers 116 may extend lengthwise in the second direction D2. As shown in FIGS. 11 and 12, the plurality of insulation layers 116 may be formed in a zigzag configuration. The plurality of drain regions 117 may be provided on the plurality of channel structures 114.

The plurality of bit lines 118a to 118c may extend lengthwise in the third direction D3. The plurality of bit lines 118a to 118c may be connected to the plurality of channel structures 114 through the plurality of drain regions 117. The plurality of channel structures 114 arranged in the third direction D3 may be electrically connected to each other through the plurality of bit lines 118a to 118c. Spaces may be formed in the plurality of interlayer insulation layers 113 between the plurality of channel structures 114 arranged in the third direction D3.

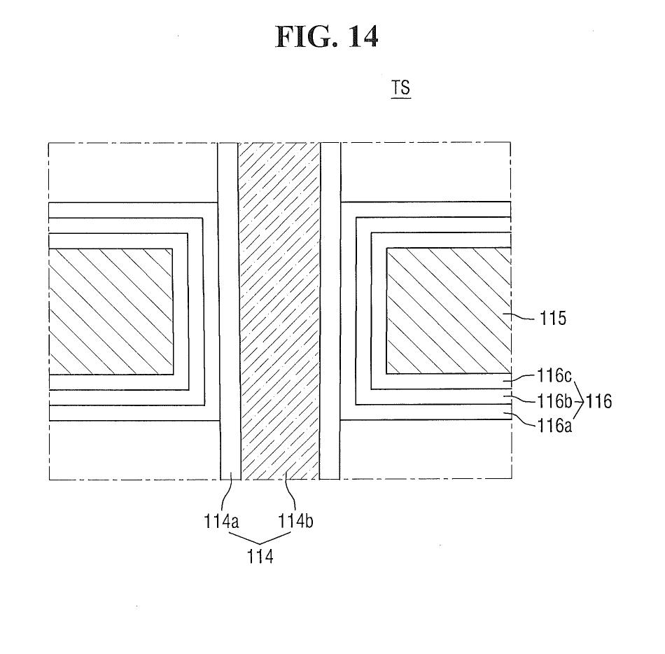

Referring now to FIG. 14, a cross-section illustrating a non-volatile memory cell (TS) shown in FIG. 13 will be discussed. As illustrated in FIG. 14, an insulation layer 116 may include a tunneling insulation layer 116a, a charge storage layer 116b and a blocking insulation layer 116c stacked one on another.

The tunneling insulation layer 116a may allow charges to pass therethrough and may be formed of, for example, a silicon oxide layer, or a dual layered structure of a silicon oxide layer and a silicon nitride layer, however, embodiments of the present inventive concept are not limited to this configuration.

The charge storage layer 116b may allow the charges having passed through the tunnel insulation layers to be stored therein. For example, the charge storage layer 116b may be formed of, for example, a nitride layer or a high-k layer. The nitride layer may include, for example, at least one selected from the group consisting of silicon nitride, silicon oxynitride, hafnium oxynitride, zirconium oxynitride, hafnium silicon oxynitride, and hafnium aluminum oxynitride. The high-k layer may be made of, for example, at least one selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The blocking insulation layer 116c may consist of a single layer or multiple layers. The blocking insulation layer 116c may include silicon oxide or an insulating metal oxide having a greater dielectric constant than silicon oxide. For example, the blocking insulation layer 116c, for example, a high-k material, such as aluminum oxide, hafnium oxide, lanthanum oxide, tantalum oxide, titanium oxide, lanthanum hafnium oxide, lanthanum aluminum oxide, or dysprosium scandium oxide, or may be formed of a combination of layers stacked.

In the channel structure 114, a non-volatile memory cell TS may be defined by a surface layer 114a, a gate pattern 115, a tunneling insulation layer 116a, a charge storage layer 116b, and a blocking insulation layer 116c.

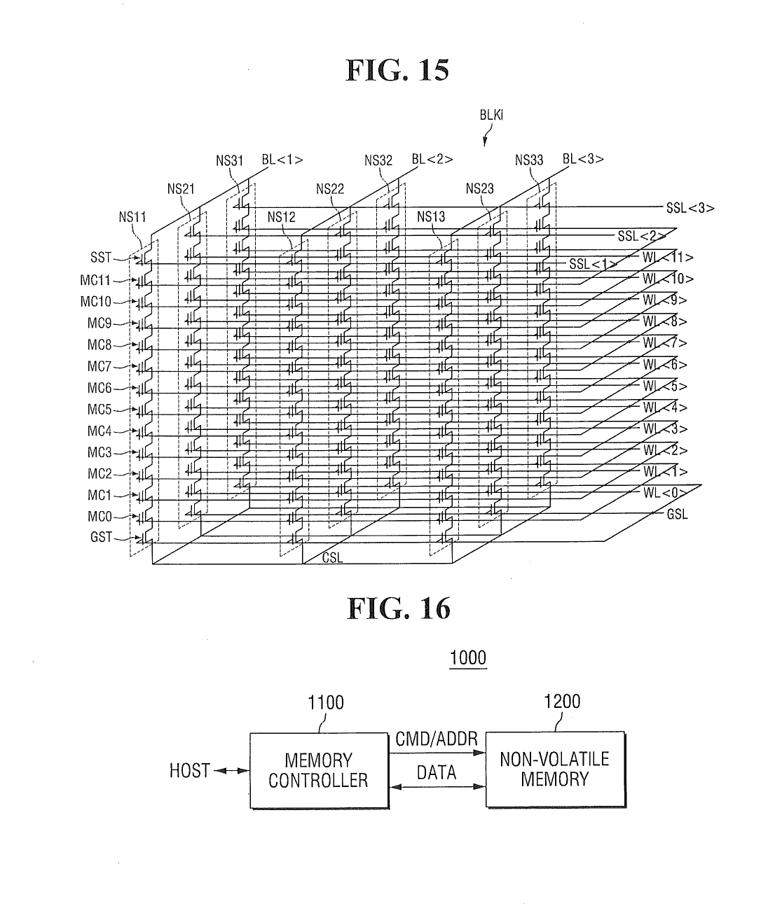

Referring now to FIG. 15, an equivalent circuit view illustrating a memory block shown in FIG. 11 will be discussed. As illustrated in FIG. 15, cell strings NS11 to NS33 are arranged between bit lines BL<1>, BL<2> and BL<3> and a common source line CSL.

The cell strings NS11, NS21 and NS31 are arranged between the bit line BL<1> and the common source line CSL. The cell strings NS12, NS22 and NS32 are arranged between the bit line BL<2> and the common source line CSL. The cell strings NS13, NS23 and NS33 are arranged between the bit line BL<3> and the common source line CSL.

String select transistors SSTs of cell strings NSs are connected to corresponding bit lines BLs. Ground select transistors GST of the cell strings NSs are connected to the common source line CSL. Memory cells MC0 MC11 are arranged between the string select transistors SSTs and the ground select transistors GSTs of the cell strings NSs.

In the following description, the cell strings NS will be divided in units of rows and columns. The cell strings NSs commonly connected to a bit line may constitute a column. For example, the cell strings NS11 to NS31 connected to the first bit line BL<1> may correspond to a first column. The cell strings NS12 to NS32 connected to the second bit line BL<2> may correspond to a second column. The cell strings NS13 to NS33 connected to the third bit line BL<3> may correspond to a third column.

The cell strings NSs connected to a string select line SSL may constitute a column. For example, the cell strings NS11 to NS13 connected to the first string select line SSL<1> may correspond to a first row. The cell strings NS21 to NS23 connected to the second string select line SSL<2> may correspond to a second row. The cell strings NS31 to NS33 connected to the third string line SSL<3> may correspond to a third row.

The cell strings NSs of the same row share the string select line SSL. Each of the cell strings NSs includes the string select transistor SST. The string select transistors SSTs of the same row may be controlled by one of string select lines SSL<1>, SSL<2> and SSL<3>.

The memory cells MCs of the same row share the word lines WLs. At the same height, the memory cells MCs of different rows share the word lines WLs.

The cell strings NSs of the same row may share the ground select line GSL. The cell strings NSs of different rows may share the ground select line GSL. Each of the cell strings NSs includes the ground select transistor GST. The ground select transistors GSTs may be controlled by one ground select line GSL. The common source line CSL is commonly connected to the cell strings NSs.

In FIGS. 11 to 15, a vertical NAND flash memory is illustrated, however, embodiments of the present inventive concept are not limited to this configuration. The read method for a non-volatile memory device according to embodiments of the present inventive concept may also be applied to a planar NAND flash memory in substantially the same manner as the vertical NAND flash memory.

Referring now to FIG. 16, a block diagram illustrating a memory system including non-volatile memory devices according to some embodiments of the present inventive concept will be discussed. As illustrated in FIG. 16, the memory system 1000 may include a memory controller 1100 and a non-volatile memory 1200.

The memory controller 1100 may be configured to control the non-volatile memory 1200 in response to a request from a host. For example, the memory controller 1100 may be configured to control program, read and erase operations of the non-volatile memory 1200. The memory controller 1100 may transmit a command CMD and an address ADDR to the non-volatile memory 1200 and may exchange data DQ with the non-volatile memory 1200. The memory controller 1100 may be configured to drive firmware for controlling the non-volatile memory 1200.

The non-volatile memory 1200 may be provided as a non-volatile memory device storing two or more bits. The non-volatile memory 1200 may be configured in substantially the same manner with the non-volatile memory devices 100 and 200 described with reference to FIGS. 1 to 8. The non-volatile memory 1200 may operate in substantially the same manner with the read method described with reference to FIGS. 9 and 10.

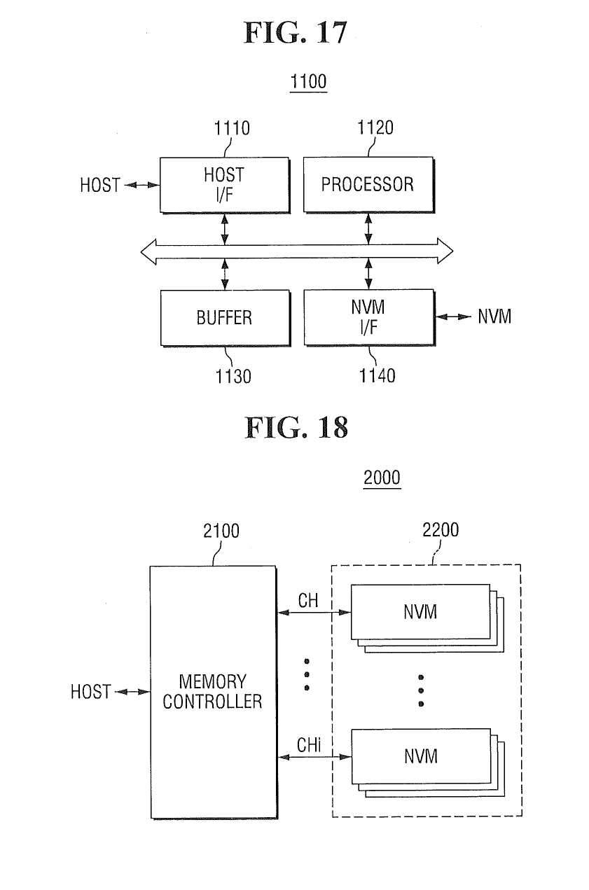

Referring now to FIG. 17, a block diagram specifically illustrating a memory controller shown in FIG. 16 will be discussed. As illustrated in FIG. 17, the memory controller 1100 includes a host interface (I/F) 1110, a processor 1120, a buffer memory 1130, and a memory interface (I/F) 1140.

The host interface 1110 may be configured to interface with a host. For example, the host interface 1110 controller may be configured to include at least one of various standardized interface protocols such as Universal Serial Bus (USB), Multimedia Card (MMC), Peripheral Component Interconnection (PCI), PCI-Express (PCI-E), Advanced Technology Attachment (ATA, Parallel-ATA, pATA), Serial-ATA (SATA), Small Computer Small Interface (SCSI), Enhanced Small Disk Interface (ESDI), and Integrated Drive Electronics (IDE). The processor 1120 may be configured to control the overall operation of the memory controller 1100.

The buffer memory 1130 may receive data to be programmed to the non-volatile memory 1200 from the host and may temporarily store the received data. During a program operation of the non-volatile memory 1200, the data temporarily stored in the buffer memory 1130 may be transmitted to the non-volatile memory 1200 to then be programmed. The buffer memory 1130 may receive data received from the non-volatile memory 1200 and may temporarily store the received data. For example, the buffer memory 1130 may be a static RAM (SRAM), however, embodiments of the present inventive concept are not limited to this configuration.

The memory interface 1140 may be configured to interface with the non-volatile memory 1200. For example, the memory interface 1140 may be configured to include NAND interface protocols, however, embodiments of the present inventive concept are not limited to this configuration.

The memory controller 1100 may further include an error correction block. The error correction block may be configured to detect errors of the data read from the non-volatile memory 1200 using an error correcting code (ECC) and to correct the detected errors.

The error correction block may be provided as a component of the memory controller 1100. Alternatively, the error correction block may also be provided as a component of the nonvolatile memory device 1200.

Referring now to FIG. 18, a block diagram illustrating an application example of the memory system shown in FIG. 17 will be discussed. For the sake of convenient explanation, the following description will focus on differences between the read methods shown in FIGS. 16 and 18.

As illustrated in FIG. 18, the memory system 2000 includes a memory controller 2100 and a non-volatile memory device 2200. The non-volatile memory device 2200 may include a plurality of non-volatile memory chips (NVMs). The NVMs may be divided into a plurality of groups. Each of the plurality of groups of the plurality of NVMs may be configured to interface with the memory controller 2100 through a common channel. For example, the plurality of NVMs may interface with the memory controller 2100 through first to ith channels CH1 to CHi.

Each of the plurality of NVMs may be configured in substantially the same manner with the non-volatile memory devices 100 and 200 described with reference to FIGS. 1 to 8. Each of the plurality of NVMs may operate in substantially the same manner with the read method described with reference to FIGS. 9 and 10. The plurality of NVMs connected to a single channel are exemplified in FIG. 18, but may also be modified such that a single NVM is connected to a single channel without departing from the scope of the present inventive concept.

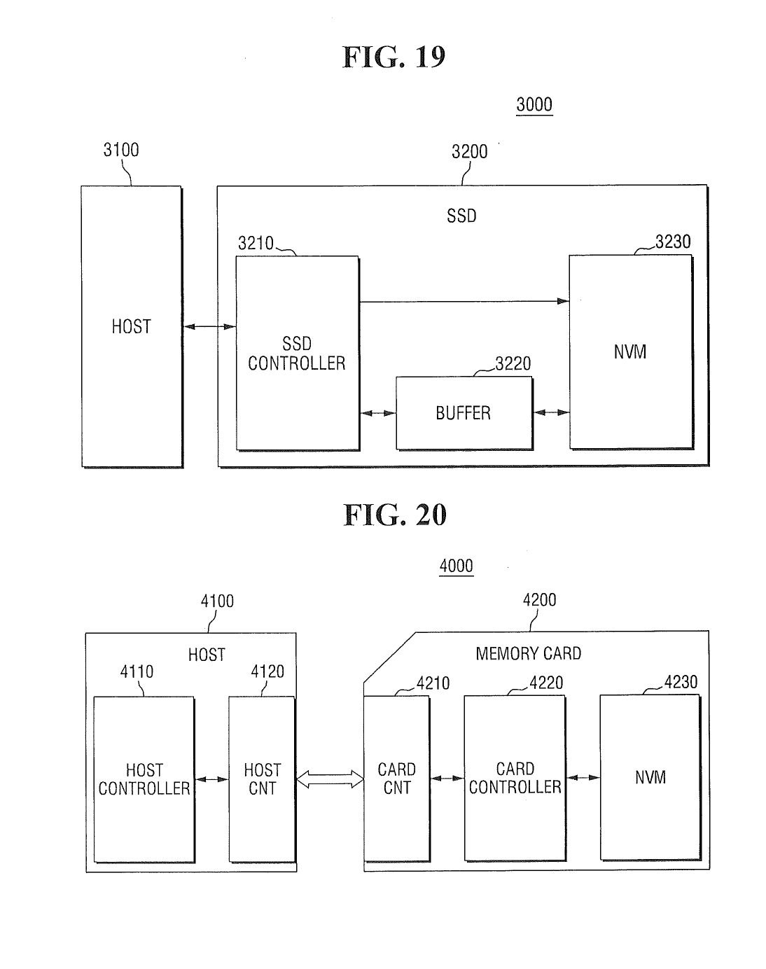

Referring now to FIG. 19, a block diagram illustrating a user system including a solid state drive (SSD) will be discussed. As illustrated in FIG. 19, the user system 3000 includes a host 3100 and a solid state drive (SSD) 3200.

The SSD 3200 includes an SSD controller 3210, a buffer memory 3220, and a non-volatile memory device (NVM) 3230. The SSD controller 3210 may interface with the host 3100. The SSD controller 3210 may access the NVM 3230 by decoding the command/address received from the host 3100. The SSD controller 3210 may transmit the data received from the host 3100 to the buffer memory 3220. The SSD controller 3210 may read data from the NVM 3230 and may provide the read data to the host 3100.

The buffer memory 3220 may be configured to temporarily store the data received from the SSD controller 3210. The buffer memory 3220 may transmit the temporarily stored data to the NVM 3230 for a program operation. In order to provide sufficient buffering capacity, the buffer memory 3220 may be provided as a synchronous DRAM (SDRAM), however, embodiments of the present inventive concept are not limited to this configuration.

The NVM 3230 may be provided as a storage medium of the SSD 3200. The NVM 3230 may be configured in substantially the same manner with the non-volatile memory devices 100 and 200 described with reference to FIGS. 1 to 8. The NVM 3230 may operate in substantially the same manner with the read method described with reference to FIGS. 9 and 10.

The buffer memory 3220 provided separately from the SSD controller 3210 is exemplified in FIG. 19, but may also be modified such that it is provided as an internal component of the SSD controller 3210.

Referring now to FIG. 20, a block diagram illustrating a user system including a memory card will be discussed. As illustrated in FIG. 20, the user system 4000 includes a host 4100, and a memory card 4200.

The host 4100 may include a host controller 4110 and a host connection unit (CNT) 4120. The memory card 4200 may include a card CNT 4210, a card controller 4220, and a non-volatile memory device (NVM) 4230.

The host CNT 4120 and the card CNT 4210 may include a plurality of pins, which include a command pin, a data pin, a clock pin, a power pin, and so on. The number of pins may vary according to the kind of the memory card 4200.

The host controller 4110 may be configured to write data to the memory card 4200 and to read data stored in the memory card 4200. The host controller 4110 may transmit the command CMD, the address ADDR, the data DQ, and the like to the memory card 4200 through the host CNT 4120.

The card controller 4220 may be configured to write data to the NVM 4230 or to read data from the NVM 4230 in response to the command received through the card CNT 4210.

The NVM 4230 may be provided as a storage medium of the memory card 4200. The NVM 4230 may be configured in substantially the same manner with the non-volatile memory devices 100 and 200 described with reference to FIGS. 1 to 8. The NVM 4230 may operate in substantially the same manner with the read method described with reference to FIGS. 9 and 10.

For example, the memory card 4200 may be a memory card, such as a PC card (for example, PCMCIA), a compact flash card (CF), a smart media card (SM/SMC), a memory stick, a multimedia card (for example, MMC, RS-MMC and MMCmicro), an SD card (for example, SD, miniSD and microSD), and a universal flash memory device (for example, UFS).

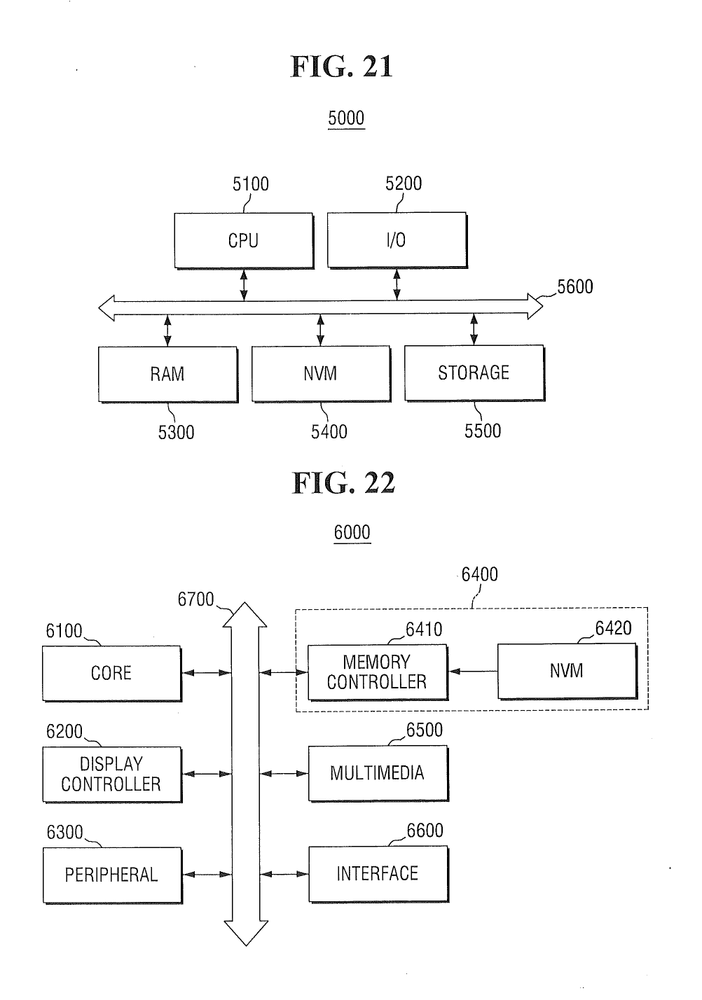

Referring now to FIG. 21, a block diagram illustrating a computing system including non-volatile memory devices according to some embodiments of the present inventive concept will be discussed. As illustrated in FIG. 21, the computing system 5000 includes a central processing unit (CPU) 5100, an input/output device (I/O) 5200, a random access memory (RAM) 5300, a non-volatile memory (ROM) 5400, a storage 5500, and a data bus 5600.

The CPU 5100, the I/O 5200, the RAM 5300, the non-volatile memory 5400, and the storage 5500 may be connected to each other through the data bus 5600. The data bus 5600 may correspond to a path through which data moves.

The CPU 5100 may include a controller, an operation unit, and so on, and may run a program to process data. The CPU 5100 may further include a cache memory positioned inside or outside.

The I/O 200 may include at least one input device capable of inputting data, such as a mouse or a keyboard, and at least one output device capable of outputting data, such as a monitor, a speaker or a printer.

The RAM 5300 may include one or more volatile memories, such as a double data rate static DRAM (DDR SDRAM) or a single data rate SDRAM (SDR SDRAM). The RAM 5300 may function as a working memory of the CPU 5100. The RAM 5300 may store the command and/or data processed by the CPU 5100.

The NVM 5400 may store the program run by the CPU 5100. The NVM 5400 may be configured in substantially the same manner with the non-volatile memory devices 100 and 200 described with reference to FIGS. 1 to 8. The NVM 5400 may operate in substantially the same manner with the read method described with reference to FIGS. 9 and 10.

The storage 5500, including recording media, such as a floppy disk, a hard disk, a CD-ROM or a DVD, may store the data and/or program.

The computing system 5000 may further include an interface device transmitting data to a communication network or receiving data from the communication network. The interface device may include, for example, an antenna, a wired/wireless transceiver, and so on.

According to some embodiments, the computing system 5000 may be an arbitrary computing system, such as a mobile phone, a smart phone, a personal digital assistant (PDA), a desktop, a notebook computer, a tablet, or the like.

Referring now to FIG. 22, a block diagram illustrating a system on chip including non-volatile memory devices according to some embodiments of the present inventive concept will be discussed. The system on chip 6000 may include a core device (CORE) 6100, a display controller 6200, a peripheral device (PERIPHERAL) 6300, a memory system (MEM) 6400, a graphic processing system 6500, an interface device (INTERFACE) 6600, and a data bus 6700.

The core device 6100, the display controller 6200, the peripheral device 6300, the memory system 6400, the graphic processing system 6500, and the interface device 6600 may be connected to each other through the data bus 6700. The data bus 6700 may correspond to a path through which data moves.

The core device 6100 may include one processor core (single-core) or a plurality of processor cores (multi-core) to process data. For example, the core device 6100 may be a multi-core, such as a dual-core, a quad-core or a hexa-core. The core device 6100 may further include a cache memory positioned inside or outside. The display controller 6200 may control a display device to allow the display device to display a picture or an image.

The peripheral device 6300 may include various devices, such as a serial communication device, a memory management device, and an audio processing device.

The memory system 6400 may be configured to store data and/or commands. The memory system 6400 may include a memory controller 6410 and a non-volatile memory 6420. The NVM 6420 may be configured in substantially the same manner with the non-volatile memory devices 100 and 200 described with reference to FIGS. 1 to 8. The NVM 5400 may operate in substantially the same manner with the read method described with reference to FIGS. 9 and 10.

The graphic processing system 6500 may include a 2D/3D graphic engine, an image signal processor (ISP), a codec engine, and so on, and may process multimedia operations.

The interface device 6600 may transmit data to a communication network or may receive data from the communication network. The interface device 6600 may include, for example, an antenna, a wired/wireless transceiver, and so on.

While the inventive concept has been particularly shown and described with reference to exemplary embodiments thereof, it will be understood that various changes in form and details may be made therein without departing from the spirit and scope of the following claims.

What is claimed is:

1. A read method for a non-volatile memory device, the read method comprising:
sensing memory cells in an Nth program state using original read voltages of an Nth level, where N is a natural number greater than 2;
counting a number of memory cells in the Nth program state based on the sensing; and
sensing memory cells in first to Nth program states using adjusted read voltages of first to Nth levels, when the number of memory cells in the Nth program state is greater than a reference number,
wherein the adjusted read voltages are obtained by adding offset voltages to the original read voltages.

2. The read method of claim 1, wherein when the number of memory cells in the Nth program state is not greater than the reference number, further comprising sensing memory cells in first to (N−1)th program states using original read voltages of first to (N−1)th levels.

3. The read method of claim 1, wherein the offset voltages are varied according to the number of memory cells in the Nth program state.

4. The read method of claim 1, wherein the offset voltages are varied according to the first to Nth program states of the memory cells.

5. The read method of claim 4, wherein the offset voltages increase at higher threshold voltages of the program states.

6. The read method of claim 4, wherein the offset voltages increase at lower threshold voltages of the program states.

7. The read method of claim 1, wherein the offset voltages are varied according to the program/erase cycle of the memory cell.

8. The read method of claim 1, wherein the offset voltages correspond to the amount of charge redistribution after programming the memory cells.

9. The read method of claim 1, wherein the adjusted read voltages are higher than the original read voltages.

10. The read method of claim 1, wherein the threshold voltage of the Nth program state among the first to Nth program states of the memory cells is highest.

11. A read method for a non-volatile memory device, the read method comprising:
sensing memory cells in an Nth program state using an original read voltage of an Nth level, where N is a natural number greater than 2;
sensing memory cells in a first program state using an original read voltage of a first level while counting the number of memory cells in the Nth program state according to the sensing; and
when the number of memory cells in the Nth program state is greater than a reference number, sensing memory cells in second to Nth program states using adjusted read voltages of second to Nth levels,
wherein the adjusted read voltages are obtained by adding offset voltages to the original read voltages.

12. The read method of claim 11, wherein when the number of memory cells in the Nth program state is not greater than the reference number, further comprising sensing memory cells in second to (N−1)th program states using original read voltages of second to (N−1)th levels.

13. The read method of claim 11, wherein the offset voltages are varied according to the number of memory cells in the Nth program state.

14. The read method of claim 11, wherein the offset voltages are varied according to the second to Nth program states of the memory cells.

15. The read method of claim 14, wherein the offset voltages increase at higher threshold voltages of the program states.

16. A read method for a non-volatile memory device, the method comprising:
when a read operation is performed before a stabilizing time, sensing program states of memory cells using adjusted read voltages;
when a read operation is conducted after the stabilizing time, sensing program states of memory cells using original read voltages, wherein the adjusted read voltages are obtained by adding offset voltages to the original read voltages.

17. The read method of claim 16, wherein the offset voltages are varied according to first to Nth program states of the memory cells.

18. The read method of claim 17, wherein the offset voltages increase at higher threshold voltages of the program states.

19. The read method of claim 17, wherein the offset voltages increase at lower threshold voltages of the program states.

20. The read method of claim 1, wherein the offset voltages are varied according to a program/erase cycle of the memory cell.
